(19) United States
(12) Patent Application Publication
(10) Pub. No.: US 2008/0029912 A1
(43) Pub. Date: Feb. 7, 2008

(54) TISIN LAYER ON SEMICONDUCTOR DEVICE

(76) Inventor: Dong-Ki Jeon, Seoul (KR)

Correspondence Address: SHERR & NOURSE, PLLC, 620 HERNDON PARKWAY, SUITE 200, HERNDON, VA, 20170, US

(21) Appl. No.: 11/831,495

(22) Filed: Jul. 31, 2007

(30) Foreign Application Priority Data
Aug. 1, 2006 (KR) 10-2006-0072667

(51) Int. Cl. H01L 23/29; H01L 21/00

(52) U.S. Cl. 257/788; 438/122; 257/E23.117; 257/E21.4

(57) ABSTRACT

A method of fabricating a titanium silicide nitride (TiSiN) layer of a semiconductor device may include forming a gate electrode on a semiconductor substrate and forming spacers on sidewalls of the gate electrode, forming a source and a drain in the semiconductor substrate, and forming TiSiN layers on the gate electrode and the source and the drain, respectively. Further, a semiconductor device may include a gate electrode, a spacer formed on sidewalls of the gate electrode, a source and a drain, wherein TiSiN layers are formed on the gate electrode, the source and the drain, respectively.

The present application claims priority under 35 U.S.C. 119 and 35 U.S.C. 365 to Korean Patent Application No. 10-2006-0072667 (filed on Aug. 1, 2006), which is hereby incorporated by reference in its entirety.

### BACKGROUND

As semiconductor devices have become more highly integrated, a width of a metal line has decreased and sheet resistance of the metal line may increase accordingly. If sheet resistance of the metal line rises, the signal transmission time of a device within an integrated circuit may be delayed. To prevent this problem, high melting-point silicide material, which may have a low resistivity and may also be stable at high temperature, may be added to the gate electrode of a transistor, and also the source/drain junction, etc. This may lower sheet resistance and contact resistance of the metal line. Rare earth metal that reacts to silicon (Si) may generally be used as such silicide material. For example, the earth metal may include tungsten silicide (WSi₂), titanium silicide (TiSi₂), cobalt silicide (CoSi₂), and so on.

FIGS. 1a to 1c are cross-sectional views sequentially illustrating a related art method of fabricating a TiSix layer of a semiconductor device.

Referring to FIG. 1a, field oxide layers 12 may be formed in silicon substrate 10 as a semiconductor substrate, defining an active region and an inactive region of the device. A gate oxide layer may be formed in an active region of silicon substrate 10. A doped polysilicon layer may be deposited and patterned to form gate electrode 14. A low-concentration impurity may be implanted into a source/drain region of silicon substrate 10 to form Lightly Doped Drain (LDD) regions 16. Spacers 18 may be formed on sidewalls of gate electrode 14 by using a silicon oxide (SiO₂) layer or a silicon nitride (Si₃N₄) layer. A high-concentration impurity may be implanted into the substrate masked by spacers 18, and may form source/drain regions 20.

Referring next to FIG. 1b, Ti layer 22 or TiN layer 24, as metal for silicide, may be deposited on the resulting surface by a process such as Physical Vapor Deposition (PVD). A thermal treatment process, such as Rapid Thermal Process (RTP), may then be performed.

Referring to FIG. 1c, TiSix layer 26 may be formed on the entire surface through a silicide reaction of the top surface of gate electrode 14 and silicon of source/drain region 20, and Ti layer 22 or TiN Layer 24 by a RTA process. Ti layer 22 or TiN Layer 24 of regions in which the silicide reaction has not occurred may be removed so that TiSix layers 26a and 26b remain only on gate electrode 14 and on the surface of source/drain region 20.

In the related art, sheet resistance can be lowered by the TiSix layer 26a on gate electrode 14 and TiSix layer 26b on the surface of source/drain region 20. Accordingly, contact resistance of a metal line, which may be brought in contact with gate electrode 14 and source/drain region 20, may be lowered.

In a related art TiSix fabrication process, however, after Ti layer 22 or TiN Layer 24 is deposited by the PVD method, a thermal treatment process such as a RTA process may be performed as described above. In this case, silicon atoms may behave as dominant diffusion sources, which may cause difficulty in forming a conformal TiSix layer 26.

Accordingly, a related art TiSix layer may be problematic in that it may be difficult to apply to highly-integrated semiconductor devices of 0.25 μm or less.

### SUMMARY

Embodiments relate to a semiconductor fabrication method. Embodiments relate to a method of fabricating a titanium silicide nitride (TiSiN) layer of a semiconductor device, which may be conformal and may have a low contact resistance in highly-integrated semiconductor devices.

Embodiments relate to a method of fabricating a TiSiN layer of a semiconductor device, in which a conformal silicide layer structure may be formed in highly-integrated semiconductor devices by fabricating a TiSiN layer in a gate electrode or a source/drain region.

According to embodiments, a method of fabricating a TiSiN layer of a semiconductor device may include forming a gate electrode on a semiconductor substrate and forming spacers on sidewalls of the gate electrode, forming a source/drain in the semiconductor substrate, and forming TiSiN layers on the gate electrode and the source/drain, respectively.

### DRAWINGS

FIGS. 1a-1c are drawings illustrating a related art method of fabricating a TiSix layer of a semiconductor device.

FIG. 2 is a vertical cross-sectional drawing of a Titanium Nitride Silicide (TiSiN) layer of a semiconductor device according to embodiments.

FIGS. 3a and 3b are cross-sectional drawings illustrating a method of fabricating a TiSiN layer of a semiconductor device according to embodiments.

FIG. 4 is a flowchart illustrating a method of fabricating a TiSiN layer of a semiconductor device according to embodiments.

FIGS. 5a-5c are drawings illustrating a method of fabricating a TiSiN layer of a semiconductor device according to embodiments.

FIG. 6 is a flowchart illustrating a method of fabricating a TiSiN layer of a semiconductor device according to embodiments.

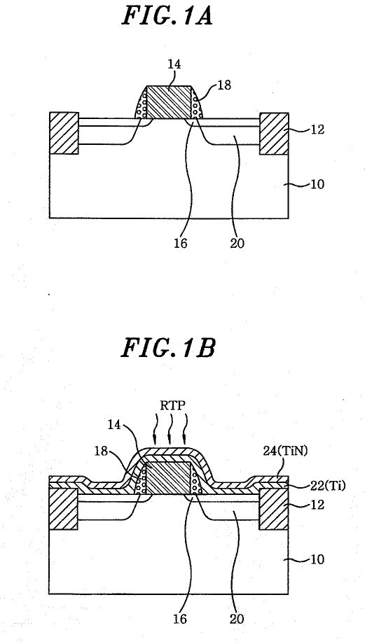

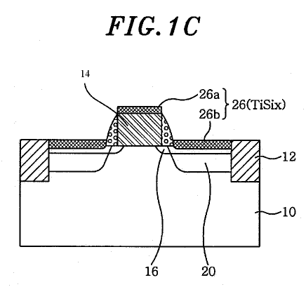

### DETAILED DESCRIPTION

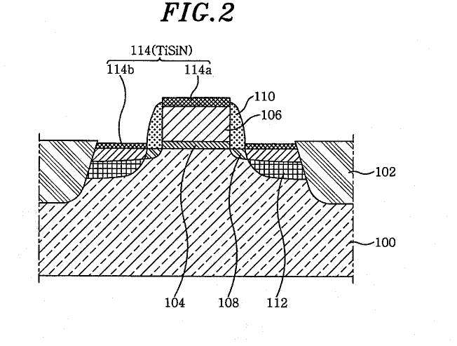

FIG. 2 is a vertical cross-sectional view of a TiSiN layer of a semiconductor device according to embodiments.

Referring to FIG. 2, a semiconductor device having a TiSiN layer according to embodiments may include field oxide layers 102 formed in a silicon substrate 100 as a semiconductor substrate. It may further include gate electrode 106 formed on an active region of silicon substrate 100 in which field oxide layers 102 may be formed. Gate oxide layer 104 may be intervened between gate electrode 106 and silicon substrate 100. LDD regions 108 may be formed in silicon substrate 100 at the edges of gate electrode 106, and spacers 110 may be formed on the sidewalls of gate electrode 106. Source/drain regions 112 may be formed in silicon substrate 100 at the edges of spacers 110, and a TiSiN layer 114 may be formed on gate electrode 106 and on the surface of source/drain region 112, respectively.

According to embodiments, TiSiN layer 114 of a semiconductor device may be formed on gate electrode 106 and/or on a surface of source/drain region 112. Thus, TiSiN layer 114 may have a conformal ohmic contact structure in highly-integrated semiconductor devices due to its conformal silicide layer material.

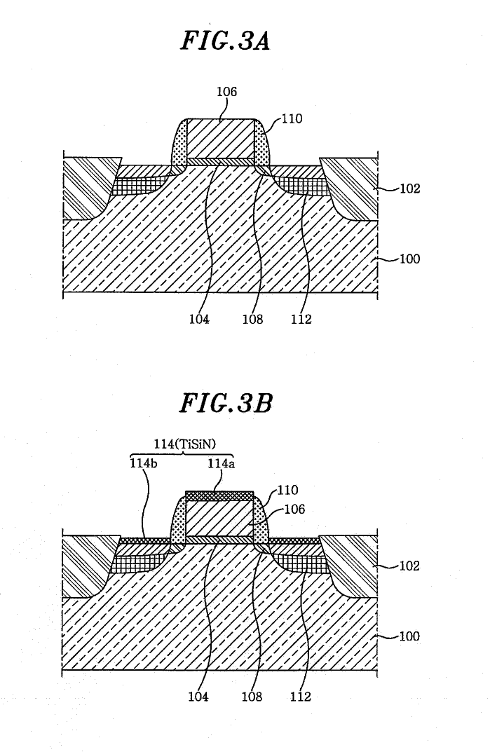

FIGS. 3a and 3b illustrate a method of fabricating the TiSiN layer of a semiconductor device according to embodiments.

Referring to FIG. 3a, field oxide layers 102 may be formed in silicon substrate 100 as a semiconductor substrate, and may define the active region and the inactive region of the device. The gate oxide layer 104 may be formed in the active region of silicon substrate 100. A doped polysilicon layer may be deposited and patterned to form gate electrode 106. A low-concentration impurity may be implanted into the source/drain region of silicon substrate 100 and may form LDD regions 108. Spacers 110 may be formed on the sidewalls of gate electrode 106 by using the silicon oxide (SiO₂) layer or the silicon nitride (Si₃N₄) layer. The high-concentration impurity may be implanted into the substrate using spacers 110 as a mask, thus forming source/drain regions 112.

Referring next to FIG. 3b, TiSiN layers 114a and 114b (114), which may be metal material for silicide, may be formed on gate electrode 106 and on a surface of source/drain region 112, respectively.

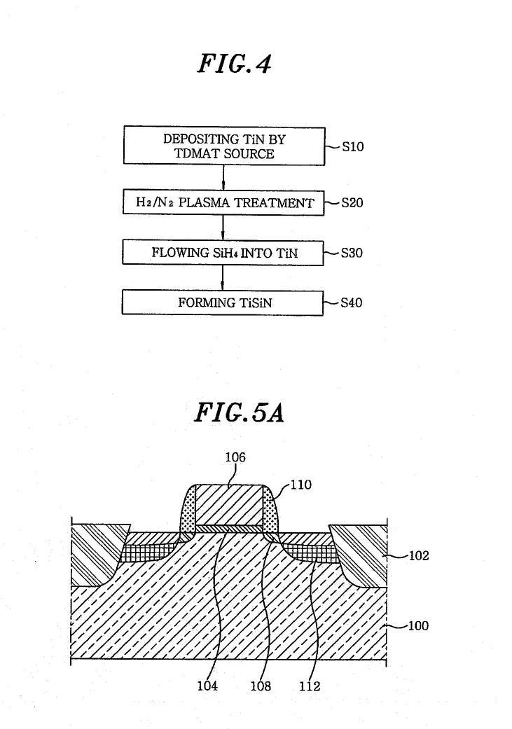

FIG. 4 is a flowchart illustrating the method of fabricating the TiSiN layer of a semiconductor device according to embodiments.

Referring to FIG. 4, in the fabrication process of TiSiN layer 114 according to embodiments, a Tetrakis Dimethyl Amino Titanium (TDMAT) source may be thermally decomposed in a Chemical Vapor Deposition (CVD) chamber to deposit a TiN layer, according to step S10. The thermal decomposition process of TDMAT may be carried out in a temperature ranging from approximately 300 to approximately 500 Celsius degrees. In embodiments, TDMAT may be carried to the CVD chamber by using helium (He) gas. In embodiments, TDMAT may be carried to the CVD chamber by a direct liquid injection method.

Plasma treatment including nonvolatile material, such as H₂/N₂ gas, may be performed on the TiN layer thermally decomposed from TDMAT, and may this remove an impurity included in TDMAT, such as hydrocarbon (CxHy), according to step S20.

In embodiments, silane (SiH₄) may be flowed into the TiN layer, from which the impurity may have been removed, at a flow rate of approximately 10 to 5000 sccm for approximately 20 to 360 seconds, and may form TiSiN layer 114, according to steps S30 and S40. In embodiments, a wet etch process of removing titanium (Ti) that has not reacted to silicon may not be performed. In embodiments, a wet etch process may be performed.

In embodiments, after TiN layer may be formed by thermally decomposing the TDMAT source on the surface of gate electrode 106 or source/drain region 112, silane (SiH₄) may be flowed and may form the TiSiN layer. It may therefore be possible to secure a conformal silicide layer even without using an additional RTA process.

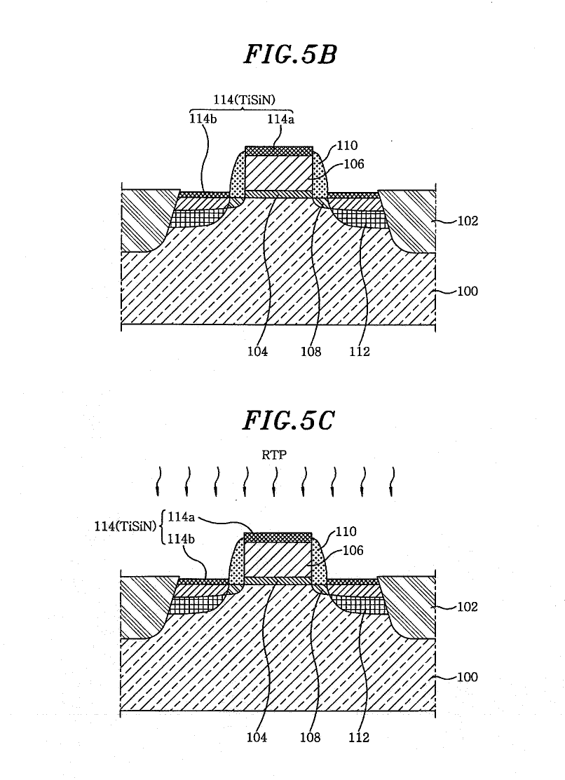

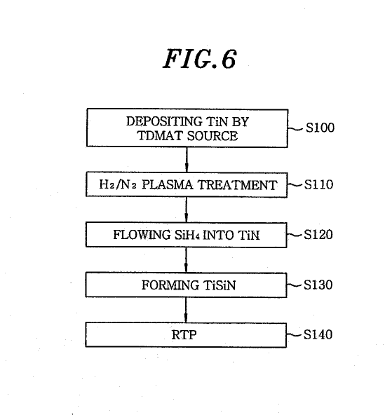

FIGS. 5a to 5c illustrate a method of fabricating a TiSiN layer of a semiconductor device according to embodiments.

FIG. 6 is a flowchart illustrating a method of fabricating the TiSiN layer of the semiconductor device according to embodiments.

Gate electrode 106, LDD regions 108, spacers 110, and source/drain regions 112 may be formed over a silicon substrate. TiSiN layers 114a and 114b (114) may be formed on gate electrode 106 and on a surface of source/drain region 112.

A TDMAT source may be thermally decomposed in a CVD chamber to deposit a TiN layer, according to step S100. The thermal decomposition process of TDMAT may be carried out in a temperature ranging from approximately 300 to approximately 500 Celsius degrees. In embodiments, TDMAT can be carried to the CVD chamber by using helium (He) gas. In embodiments, TDMAT can be carried to the CVD chamber by a direct liquid injection method.

In embodiments, H₂/N₂ plasma treatment including nonvolatile material, such as H₂/N₂ gas, may be performed on the TiN layer thermally decomposed from TDMAT, and may thus remove an impurity included in TDMAT, such as hydrocarbon (CxHy), according to step S110.

Silane (SiH₄) of approximately 10 to 5000 sccm may be flowed into the TiN layer from which the impurity has been removed for approximately 20 to 360 seconds, and may form TiSiN layer 114, according to steps S120 and S130. In embodiments, a wet etch process of removing titanium (Ti) that has not reacted to silicon may not be performed.

In embodiments, a RTA process as a thermal treatment process may be performed on TiSiN layer 114, which may achieve a deeper silicide layer, according to step S140. Accordingly, contact resistance may be lowered further.

In embodiments, since the TiSiN layer may be formed on the gate electrode or the source/drain region, a conformal silicide layer structure may be formed in a highly-integrated semiconductor devices compared with a related art TiSix layer formed by a Physical Vapor Deposition (PVD) process and a thermal treatment process. Accordingly, there may be an advantage in that contact resistance of semiconductor devices may be lowered significantly.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a gate electrode over a semiconductor substrate and forming spacers on sidewalls of the gate electrode;
forming a source and a drain in the semiconductor substrate; and
forming TiSiN layers over the gate electrode and the source and the drain, respectively.

2. The method of claim 1, wherein forming the TiSiN layer comprises:
thermally decomposing a Tetrakis Dimethyl Amino Titanium (TDMAT) source in a Chemical Vapor Deposition (CVD) chamber to deposit a TiN layer;
performing plasma treatment on the TiN layer to remove an impurity included in TDMAT; and
flowing silane (SiH₄) into the TiN layer from which the impurity has been removed, to form the TiSiN layer.

3. The method of claim 2, wherein the thermal decomposition process of the TDMAT is performed at a temperature ranging from 300 to 500 Celsius degrees.

4. The method of claim 2, wherein the TDMAT is carried to the CVD chamber using helium (He) gas.

5. The method of claim 2, wherein the TDMAT is carried to the CVD chamber by a direct liquid injection method.

6. The method of claim 2, wherein the plasma treatment is performed using a nonvolatile material.

7. The method of claim 6, wherein the nonvolatile material comprises at least one of H₂ and N₂ gas.

8. The method of claim 2, wherein the silane (SiH₄) is flowed at a rate of 10 to 5000 sccm for 20 to 360 seconds.

9. The method of claim 2, further comprising performing a wet etch process to remove titanium (Ti) that has not reacted to silicon.

10. The method of claim 2, further comprising performing a thermal treatment process on the TiSiN layer after forming the TiSiN layer.

11. A semiconductor device, comprising:
a gate electrode;
a spacer formed on sidewalls of the gate electrode; and
a source and a drain,
wherein TiSiN layers are formed over the gate electrode, the source, and the drain, respectively.

12. The device of claim 11, wherein the TiSiN layer is formed by a process comprising:
thermally decomposing a Tetrakis Dimethyl Amino Titanium (TDMAT) source in a Chemical Vapor Deposition (CVD) chamber to deposit a TiN layer;
performing plasma treatment on the TiN layer in order to remove an impurity included in TDMAT; and
flowing silane (SiH₄) into the TiN layer from which the impurity has been removed, forming a TiSiN layer.

13. The device of claim 12, wherein the thermal decomposition process of the TDMAT is performed in a temperature ranging from 300 to 500 Celsius degrees.

14. The device of claim 12, wherein the TDMAT is carried to the CVD chamber using helium (He) gas.

15. The device of claim 12, wherein the TDMAT is carried to the CVD chamber by a direct liquid injection method.

16. The device of claim 12, wherein the plasma treatment is performed using a nonvolatile material.

17. The device of claim 16, wherein the nonvolatile material comprises at least one of H₂ and N₂ gas.

18. The device of claim 12, wherein the silane (SiH₄) is flowed at a rate of 10 to 5000 sccm for 20 to 360 seconds.

19. The device of claim 12, wherein a wet etch process is performed to remove titanium (Ti) that has not reacted to silicon.

20. The device of claim 12, wherein a thermal treatment process is performed on the TiSiN layer after the TiSiN layer is formed.
